(19) United States
(12) Patent Application Publication
(10) Pub. No.: US 2013/0278910 A1
(43) Pub. Date: Oct. 24, 2013

(54) PROJECTION OPTICAL ASSEMBLY, PROJECTION OPTICAL ASSEMBLY ADJUSTMENT METHOD, EXPOSURE DEVICE, EXPOSURE METHOD, AND DEVICE MANUFACTURING METHOD

(71) Applicant: Nikon Corporation, (US)

(72) Inventors: Hironori Ikezawa, Fukaya-shi (JP); Takeshi Tsuda, Tokyo (JP)

(21) Appl. No.: 13/852,566

(22) Filed: Mar. 28, 2013

Related U.S. Application Data
(63) Continuation of application No. PCT/JP2011/069916, filed on Sep. 1, 2011.
(60) Provisional application No. 61/388,212, filed on Sep. 30, 2010.

(51) Int. Cl. G03F 7/20

(52) U.S. Cl. CPC G03F 7/70141
USPC 355/67

(57) ABSTRACT

An embodiment is a projection optical assembly capable of controlling aberration variation due to irradiation with light at a low level. The projection optical assembly for forming an image of a first surface on a second surface, using light of a predetermined wavelength is provided with a correction member to generate an aberration in a tendency opposite to a tendency of the aberration generated in the projection optical assembly by irradiation with the light of the predetermined wavelength. The correction member is a light transmissive member having an absorption loss of not less than 2% for the light of the predetermined wavelength. For example, at least one of a base material of the correction member and a thin film on the base material has the absorption loss of not less than 2% for the light of the predetermined wavelength.

### CROSS-REFERENCE TO RELATED APPLICATIONS

This application is a continuation of International Application PCT/JP2011/069916 claiming the benefit of the priority of U.S. provisional Application No. 61/388,212 filed on Sep. 30, 2010, and the contents of these U.S. provisional Application and International Application are intended to be incorporated herein all by this reference in their entirety.

### BACKGROUND

1. Field

The present embodiment relates to a projection optical assembly, a projection optical assembly adjustment method, an exposure device, an exposure method, and a device manufacturing method. More particularly, the embodiments of the present embodiment relate to suppression of aberration variation due to irradiation with exposure light in a projection optical assembly mounted on an exposure device.

2. Disclosure of Related Art

An exposure device is used as one to project a pattern of a mask (or a reticle) onto a photosensitive substrate (a wafer or a plate coated with a resist, or the like) to expose it, for example, in manufacturing devices such as semiconductor devices, imaging devices, liquid crystal display devices, and thin film magnetic heads by lithography. In the exposure device of this kind, the projection optical assembly with good optical performance is designed to accurately transfer the microscopic pattern of the mask onto the photosensitive substrate.

However, base materials of lenses and thin films thereon are subject to rise in temperature when the lenses (which are a general concept embracing plane-parallel plates) forming the projection optical assembly are irradiated with light during continuous exposure. This temperature rise results in causing change in refractive index inside the lenses and surface expansion and inducing aberration variation due to the light irradiation eventually. The aberration variation due to the light irradiation can be corrected (or adjusted) in real time by finely moving one or more lenses in the axial direction or in a direction perpendicular to the optical axis (e.g., reference is made to U.S. Pat. Published Application No. 2008/0062391).

### SUMMARY

An example of the present embodiment provides a projection optical assembly for forming an image of a first surface on a second surface, using light of a predetermined wavelength,

the projection optical assembly comprising: a correction member which, when irradiated with the light of the predetermined wavelength, generates an aberration in a tendency opposite to a tendency of the aberration generated in the projection optical assembly by irradiation with the light of the predetermined wavelength,

wherein the correction member is a light transmissive member having an absorption loss of not less than 2% for the light of the predetermined wavelength.

### BRIEF DESCRIPTION OF SEVERAL VIEWS OF DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary drawing schematically showing a configuration of an exposure device according to the present embodiment;

FIG. 2 is an exemplary drawing showing a lens configuration of a projection optical assembly according to the present embodiment;

FIGS. 3A and 3B are exemplary drawings explaining a distortion difference between distortions in two directions perpendicular to each other on an image plane of the projection optical assembly;

FIG. 4 is an exemplary flowchart showing a projection optical assembly adjustment method according to the present embodiment;

FIG. 5 is an exemplary drawing schematically showing a configuration of a correction member according to each embodiment;

FIG. 6 is an exemplary drawing explaining an axial astigmatic difference between a vertical line pattern and a horizontal line pattern;

FIG. 7 is an exemplary drawing showing a first example of the projection optical assembly equipped with the correction member;

FIG. 8 is an exemplary drawing showing a second example of the projection optical assembly equipped with the correction member;

FIG. 9 is an exemplary flowchart showing manufacturing blocks of semiconductor devices; and

FIG. 10 is an exemplary flowchart showing manufacturing blocks of a liquid crystal device such as a liquid crystal display device.

### DETAILED DESCRIPTION

Various embodiments will be described below on the basis of the accompanying drawings.

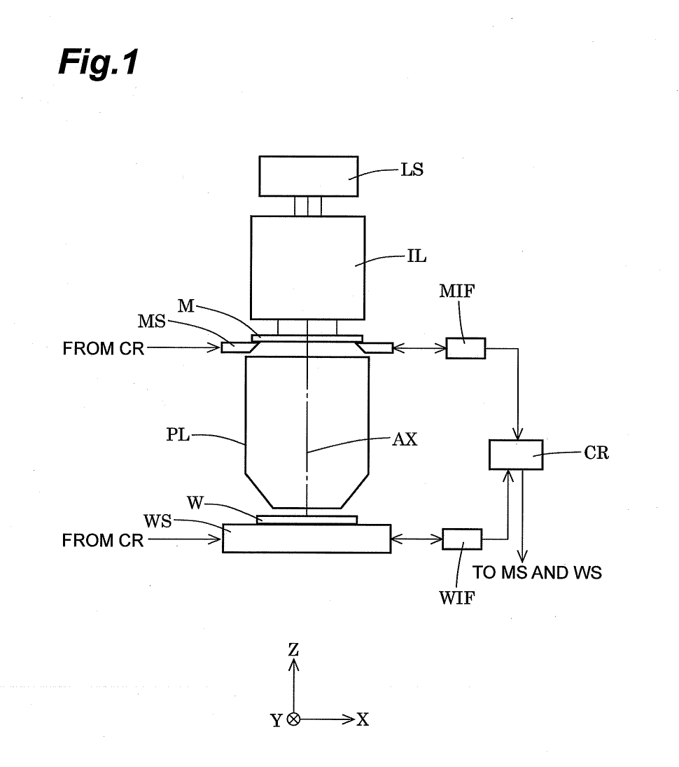

FIG. 1 is an exemplary drawing schematically showing a configuration of an exposure device according to the present embodiment. In FIG. 1, X-axis and Y-axis are set to be perpendicular to each other in a plane parallel to a surface (transfer surface) of a wafer W, and Z-axis is set along a direction of a normal to the surface of the wafer W. More specifically, the XY plane is set horizontal and the +Z-axis is set upward along the vertical direction.

With reference to FIG. 1, a light source LS supplies exposure light (illumination light) in the exposure device of the present embodiment. The light source LS has, for example, an ultrahigh-pressure mercury lamp and supplies as the exposure light, light of the i-line (wavelength of 365.065 nm) selected from light emitted therefrom. The exposure device of the present embodiment is provided with an illumination optical assembly IL, a mask stage MS, a projection optical assembly PL, a substrate stage WS, and a controller CR. The illumination optical assembly IL is composed, for example, of a spatial light modulator (diffraction optical element), an optical integrator (homogenizer), a field stop, a condenser optical system, and so on.

The illumination optical assembly IL illuminates a mask (reticle) M on which a pattern to be transferred is formed, with the exposure light (illumination light) emitted from the light source LS. In the case of the exposure device of the step-and-repeat method, the illumination optical assembly IL illuminates the whole of a pattern region of a rectangular shape on the mask M. In the case of the exposure device of the step-and-scan method, the illumination optical assembly IL illuminates a region of a rectangular shape elongated along the X-direction perpendicular to the Y-direction being a scanning direction, in the pattern region of the rectangular shape.

After passing through a pattern surface of the mask M, the light travels through the projection optical assembly PL, for example, having a reduction magnification, to form a pattern image of the mask M in a unit exposure region on the wafer (photosensitive substrate) W coated with a photoresist. Namely, the mask pattern image is formed in a rectangular region similar to the entire pattern region of the mask M or in a region of a rectangular shape elongated in the X-direction (still exposure region), in a unit exposure region of the wafer W so as to optically correspond to the illumination region on the mask M.

The mask M is held in parallel with the XY plane on the mask stage MS. The mask stage MS incorporates a mechanism for moving the mask M in the X-direction, Y-direction, Z-direction, and direction of rotation around the Z-axis. The mask stage MS is provided with a moving mirror not shown, and a mask laser interferometer MIF using this moving mirror measures an X-directional position, a Y-directional position, and a position in the direction of rotation around the Z-axis of the mask stage MS (and the mask M eventually) in real time.

The wafer W is held in parallel with the XY plane on the substrate stage WS through a wafer holder (not shown). The substrate stage WS incorporates a mechanism for moving the wafer W in the X-direction, Y-direction, Z-direction, and direction of rotation around the Z-axis. The substrate stage WS is provided with a moving mirror not shown, and a substrate laser interferometer WIF using this moving mirror measures an X-directional position, a Y-directional position, and a position in the direction of rotation around the Z-axis of the substrate stage WS (and the wafer W eventually) in real time.

The output from the mask laser interferometer MIF and the output from the substrate laser interferometer WIF are supplied to the controller CR. The controller CR performs control on the X-directional position, Y-directional position, and position in the direction of rotation around the Z-axis of the mask M, based on the measurement result by the mask laser interferometer MIF. Namely, the controller CR sends a control signal to the mechanism incorporated in the mask stage MS and this mechanism moves the mask stage MS, based on the control signal, thereby to adjust the X-directional position, Y-directional position, and position in the direction of rotation around the Z-axis of the mask M.

The controller CR performs control on the Z-directional position of the wafer W (focus position), in order to align the surface of the wafer W with the image plane of the projection optical assembly PL by the autofocus method. Furthermore, the controller CR performs control on the X-directional position, Y-directional position, and position in the direction of rotation around the Z-axis of the wafer W, based on the measurement result by the substrate laser interferometer WIF. Namely, the controller CR sends a control signal to the mechanism incorporated in the substrate stage WS and this mechanism moves the substrate stage WS, based on the control signal, thereby to adjust the X-directional position, Y-directional position, and position in the direction of rotation around the Z-axis of the wafer W.

In the step-and-repeat method, the pattern image of the mask M is projected by one-shot exposure in one unit exposure region out of a plurality of unit exposure regions set lengthwise and crosswise on the wafer W. Thereafter, the controller CR stepwise moves the substrate stage WS along the XY plane, thereby to position another unit exposure region on the wafer W relative to the projection optical assembly PL. In this manner, the operation is repeated to implement one-shot exposure of the pattern image of the mask M in each unit exposure region on the wafer W.

In the step-and-scan method, the controller CR performs control to implement scanning exposure of the mask pattern of the mask M in one unit exposure region on the wafer W, while moving the mask stage MS and the substrate stage WS at a speed ratio according to the projection magnification of the projection optical assembly PL in the Y-direction. Thereafter, the controller CR stepwise moves the substrate stage WS along the XY plane, thereby to position another unit exposure region on the wafer W relative to the projection optical assembly PL. In this manner, the operation is repeated to implement scanning exposure of the pattern image of the mask M in each unit exposure region on the wafer W.

Namely, the step-and-scan method is carried out as follows; while performing the position control of the mask M and the wafer W, the mask stage MS and the substrate stage WS are synchronously moved (or scanned) to move the mask M and the wafer S eventually, along the Y-direction being the short-side direction of the still exposure region of the rectangular shape, whereby the mask pattern is projected by scanning exposure onto a region having the width equal to the length of the long sides of the still exposure region and the length according to a scanning distance (moving distance) of the wafer W, on the wafer W.

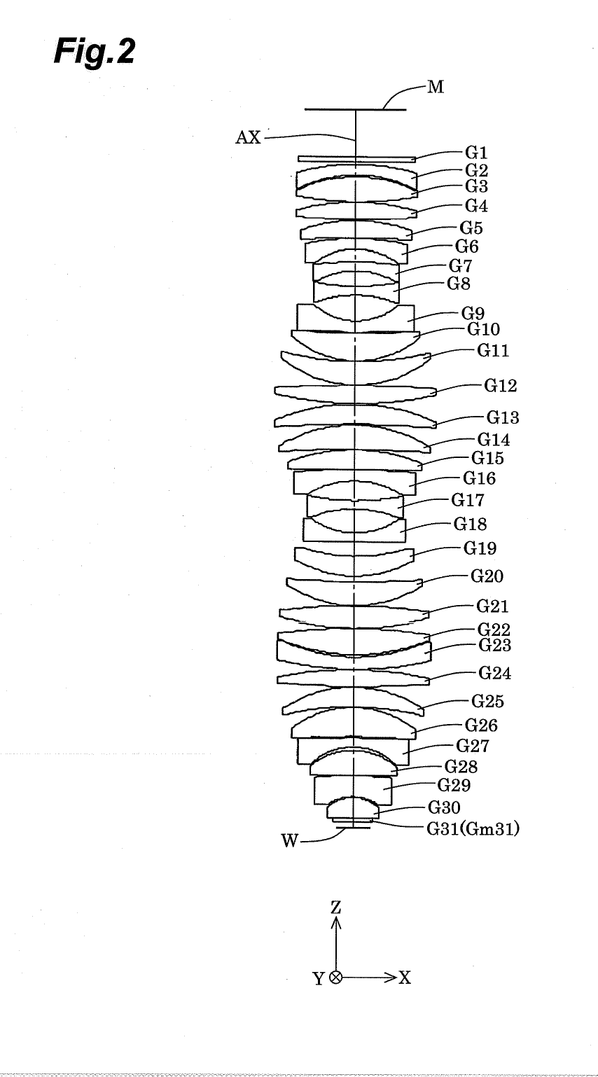

FIG. 2 is an exemplary drawing showing a lens configuration of the projection optical assembly according to the present embodiment. With reference to FIG. 2, the projection optical assembly PL of the present embodiment is provided with a plane-parallel plate G1, twenty nine lenses G2-G30, and a plane-parallel plate G31, which are arranged in the order named from the mask M side. The plane-parallel plate G1, lens G28, and lens G30 are formed of quartz having the refractive index of 1.47458 for the used light (exposure light) of the i-line (wavelength: 365.065 nm). The lens G2, lens G5, lens G9, lens G17, lens G18, and lens G27 are formed of an optical material A having the refractive index of 1.61290 for the exposure light.

The lens G3, lens G7, lens G8, lens G10, lens G15, lens G19, lens G20, lens G21, lens G22, lens G24, lens G25, lens G26, and lens G29 are formed of an optical material B having the refractive index of 1.48804 for the exposure light. The lens G4, lens G6, lens G11, lens G12, lens G13, lens G14, lens G16, lens G23, and plane-parallel plate G31 are formed of an optical material C having the refractive index of 1.61546 for the exposure light.

A concave surface of the lens G5 on the wafer W side, a concave surface of the lens G8 on the wafer W side, a concave surface of the lens G17 on the mask M side, and a concave surface of the lens G26 on the wafer W side are formed in aspheric shape. An aspheric surface is represented by Mathematical Expression (a) below, where y represents a height in a direction normal to the optical axis, z a distance (sag) along the optical axis from a tangent plane at a top of the aspheric surface to a position on the aspheric surface at the height y, r the radius of curvature at the top, K the conic constant, and Cₙ an nth-order aspheric coefficient. In Table (1) described below, each lens surface formed in aspheric shape is accompanied by mark * to the right of a surface number.

z=(y²/r)/[1+{1−κ·y²/r²}^{1/2}]+C₄·y⁴+C₈·y⁶+C₈·y⁸+C₁₀·y¹⁰+C₁₂·y¹² (a)

In the present embodiment, the mask M is illuminated by circular illumination with the σ value of 0.70 (σ value=mask-side numerical aperture of the illumination optical assembly/mask-side numerical aperture of the projection optical assembly). In accordance with the step-and-repeat method, the pattern image of the mask M is projected by one-shot exposure in each unit exposure region of the rectangular shape having the size of 26 mm×33 mm on the wafer W. At this time, the energy amount arriving at each unit exposure region is 4 kW.

Table (1) below shows a list of specifications of the projection optical assembly according to the present embodiment. In the column of major specifications in Table (1), A represents the wavelength of the exposure light, β the magnitude of the projection magnification, NA the image-side (wafer-side) numerical aperture, and σ the σ value. In the column of specifications of optical members in Table (1), face No. represents a number of each surface counted from the mask side, r a radius of curvature of each surface (a radius of curvature at a top for an aspheric surface: mm), d an axial spacing or surface separation (mm) of each surface, and n the refractive index for the wavelength of the exposure light.

In the column of specifications of optical members in Table (1), φe represents an effective diameter of each surface, and φp a partial diameter of each surface. The partial diameter φp of each surface herein is defined as follows: when each surface is illuminated with a beam emitted with a maximum object-side numerical aperture from a point on the optical axis on a first surface, the partial diameter is the smaller of a diameter and a minor axis of an illuminated region on the pertinent surface.

In the column of data of optical materials in Table (1), absorption (%/1 cm) represents an absorption loss caused when the light traveling along the optical axis AX of the projection optical assembly PL (which will also be referred to hereinafter as “axial ray”) has passed 1 cm through a light transmissive member comprised of each optical material. dn/dT represents a ratio of change dn of the refractive index (refractive index for the exposure light) n of each optical material to change dT of temperature T.

TABLE (1)
(Major Specifications)
λ = 365.065 nm
β = ¼
NA = 0.62
σ = 0.70
(Specifications of Optical Members)

| | | | | | | | optical member |
|---|---|---|---|---|---|---|---|
| face No. | r | d | n | φe | φp | φe/φp | (optical material) |
| | (mask surface) | 75.501 | | | | | |
| 1 | ∞ | 8.000 | 1.47458 | 191.8 | 23.7 | 0.124 | (G1; quartz) |
| 2 | ∞ | 5.000 | | 193.5 | 25.4 | 0.131 | |
| 3 | 359.452 | 18.500 | 1.61290 | 199.5 | 27.0 | 0.136 | (G2: A) |
| 4 | 213.483 | 3.197 | | 198.6 | 30.1 | 0.152 | |
| 5 | 231.185 | 43.422 | 1.48804 | 199.5 | 31.2 | 0.157 | (G3: B) |
| 6 | −586.659 | 1.000 | | 200.6 | 39.4 | 0.196 | |
| 7 | 365.036 | 31.316 | 1.61546 | 199.7 | 39.9 | 0.200 | (G4: C) |
| 8 | −914.807 | 1.000 | | 196.9 | 43.4 | 0.220 | |
| 9 | 263.755 | 30.100 | 1.61290 | 184.6 | 43.7 | 0.237 | (G5: A) |
| 10* | 1330.000 | 1.000 | | 174.2 | 44.6 | 0.256 | |
| 11 | 391.114 | 18.500 | 1.61546 | 168.0 | 44.7 | 0.266 | (G6: C) |
| 12 | 118.824 | 21.922 | | 143.5 | 44.8 | 0.312 | |
| 13 | 588.191 | 15.000 | 1.48804 | 142.9 | 49.7 | 0.348 | (G7: B) |
| 14 | 133.484 | 26.649 | | 134.6 | 52.0 | 0.386 | |
| 15 | −379.732 | 15.000 | 1.48804 | 134.9 | 61.3 | 0.455 | (G8: B) |
| 16* | 163.050 | 45.382 | | 142.2 | 67.8 | 0.477 | |
| 17 | −107.039 | 20.831 | 1.61290 | 144.5 | 91.2 | 0.631 | (G9: A) |
| 18 | −2587.598 | 1.000 | | 196.6 | 115.9 | 0.590 | |
| 19 | −2955.499 | 49.335 | 1.48804 | 199.4 | 117.5 | 0.589 | (G10: B) |
| 20 | −165.449 | 1.000 | | 213.8 | 146.6 | 0.686 | |
| 21 | −520.779 | 41.165 | 1.61546 | 240.4 | 156.9 | 0.652 | (G11: C) |
| 22 | −201.528 | 1.000 | | 249.9 | 174.0 | 0.696 | |
| 23 | 1746.197 | 32.262 | 1.61546 | 268.9 | 184.0 | 0.684 | (G12: C) |
| 24 | −610.410 | 1.000 | | 271.0 | 189.0 | 0.697 | |
| 25 | 337.909 | 35.076 | 1.61546 | 271.1 | 192.7 | 0.711 | (G13: C) |
| 26 | 1750.652 | 1.000 | | 267.3 | 189.8 | 0.710 | |
| 27 | 245.291 | 42.021 | 1.61546 | 253.8 | 187.5 | 0.739 | (G14: C) |
| 28 | 1489.097 | 1.000 | | 245.4 | 177.3 | 0.722 | |
| 29 | 302.839 | 33.589 | 1.48804 | 225.6 | 171.2 | 0.759 | (G15: B) |
| 30 | ∞ | 1.000 | | 213.8 | 159.0 | 0.744 | |
| 31 | 1168.044 | 19.663 | 1.61546 | 203.9 | 155.8 | 0.764 | (G16: C) |
| 32 | 144.707 | 35.696 | | 163.0 | 135.9 | 0.834 | |
| 33* | −429.000 | 15.000 | 1.61290 | 161.2 | 131.8 | 0.817 | (G17: A) |
| 34 | 205.000 | 41.014 | | 150.3 | 130.1 | 0.865 | |
| 35 | −127.766 | 15.500 | 1.61290 | 150.3 | 133.9 | 0.891 | (G18: A) |
| 36 | ∞ | 24.801 | | 171.4 | 156.5 | 0.913 | |
| 37 | −300.628 | 35.644 | 1.48804 | 181.2 | 170.9 | 0.943 | (G19: B) |
| 38 | −197.530 | 10.000 | | 199.5 | 192.8 | 0.966 | |
| 39 | −1530.451 | 40.547 | 1.48804 | 221.0 | 220.4 | 0.997 | (G20: B) |
| 40 | −212.500 | 1.000 | | 227.5 | 227.5 | 1.000 | |
| 41 | 947.366 | 37.332 | 1.48804 | 247.8 | 241.5 | 0.974 | (G21: B) |
| 42 | −469.461 | 1.000 | | 251.2 | 243.3 | 0.969 | |
| 43 | 916.672 | 46.877 | 1.48804 | 255.0 | 241.9 | 0.949 | (G22: B) |
| 44 | −326.966 | 3.818 | | 255.0 | 239.9 | 0.941 | |
| 45 | −297.381 | 21.500 | 1.61546 | 254.5 | 238.9 | 0.938 | (G23: C) |
| 46 | −564.534 | 1.000 | | 258.3 | 238.3 | 0.923 | |
| 47 | 624.794 | 29.330 | 1.48804 | 254.9 | 231.0 | 0.906 | (G24: B) |
| 48 | −1788.378 | 1.000 | | 252.4 | 226.1 | 0.896 | |
| 49 | 209.063 | 34.271 | 1.48804 | 235.9 | 208.0 | 0.882 | (G25: B) |
| 50 | 475.000 | 1.000 | | 227.8 | 195.5 | 0.858 | |
| 51 | 164.691 | 52.400 | 1.48804 | 208.6 | 179.6 | 0.861 | (G26: B) |
| 52* | 925.765 | 2.252 | | 189.2 | 150.3 | 0.794 | |
| 53 | 1890.372 | 15.500 | 1.61290 | 187.3 | 148.1 | 0.791 | (G27: A) |
| 54 | 100.768 | 6.281 | | 145.5 | 117.4 | 0.807 | |
| 55 | 13.712 | 42.000 | 1.47458 | 145.0 | 115.3 | 0.796 | (G28: quartz) |
| 56 | ∞ | 1.000 | | 132.9 | 93.8 | 0.705 | |
| 57 | 555.241 | 38.699 | 1.48804 | 127.2 | 90.0 | 0.707 | (G29: B) |
| 58 | 77.457 | 1.000 | | 86.3 | 53.1 | 0.615 | |
| 59 | 66.183 | 35.107 | 1.47458 | 84.4 | 51.6 | 0.612 | (G30: quartz) |
| 60 | ∞ | 1.000 | | 66.0 | 24.0 | 0.363 | |
| 61 | ∞ | 6.000 | 1.61546 | 64.4 | 22.4 | 0.347 | (G31: C) |
| 62 | ∞ | 11.000 | | 59.4 | 17.4 | 0.293 | |
| | (wafer surface) | | | | | | |

(Data of Aspheric Surfaces)

10th surface
κ = 1
C₄ = 1.31822 × 10⁻⁸ C₆ = −4.89799 × 10⁻¹³
C₈ = 1.16334 × 10⁻¹⁷ C₁₀ = −1.24523 × 10⁻²¹
C₁₂ = 0
16th surface
κ = 1
C₄ = −7.05620 × 10⁻⁸ C₆ = −1.72163 × 10⁻¹²
C₈ = −7.45674 × 10⁻¹⁸ C₁₀ = −4.91795 × 10⁻²²
C₁₂ = 0
33rd surface
κ = 1
C₄ = −2.54664 × 10⁻⁸ C₆ = 1.0245 × 10⁻¹²
C₈ = 1.13552 × 10⁻¹⁷ C₁₀ = −7.73875 × 10⁻²²
C₁₂ = 3.78072 × 10⁻²⁷
52nd surface
κ = 1
C₄ = −2.48423 × 10⁻⁸ C₆ = 1.03921 × 10⁻¹²
C₈ = −1.52722 × 10⁻¹⁷ C₁₀ = −7.18477 × 10⁻¹⁷
C₁₂ = 3.09423 × 10⁻²⁶

(Data of Optical Materials)

| optical | absorption | | linear expansion |
|---|---|---|---|
| material type | (%/1 cm) | dn/dT | coefficient |
| quartz | 0.0 | 1.15 × 10⁻⁵ | 5.40 × 10⁻⁷ |
| optical material A | 0.4 | 5.80 × 10⁻⁶ | 1.10 × 10⁻⁵ |
| optical material B | 0.1 | −4.80 × 10⁻⁶ | 1.63 × 10⁻⁵ |
| optical material C | 0.3 | 5.00 × 10⁻⁶ | 6.10 × 10⁻⁶ |

In the present embodiment, the same antireflection film (thin film) is formed on the both surfaces of the base materials of all the light transmissive members G1-G31. The absorption loss caused by passage of the axial ray through one antireflection film is 0.05% (=0.0005). Therefore, with consideration of absorption losses in the base materials of the thirty one light transmissive members G1-G31 and absorption losses in the sixty two (=31×2) antireflection films, the transmittance TL about the axial ray of the projection optical assembly PL is 75.0% (=0.750).

The projection optical assembly PL according to the present embodiment is designed so as to suitably correct aberrations for the exposure light and so as to ensure satisfactory optical performance eventually. However, when the lenses (the general concept embracing plane-parallel plates) forming the projection optical assembly PL are irradiated with the exposure light, aberration variation occurs due to the light irradiation. The aberration variation due to the light irradiation can be corrected (or adjusted) in real time by finely moving one or more lenses in the axial direction or in the direction perpendicular to the optical axis. It is, however, difficult to correct a distortion difference between distortions in two directions perpendicular to each other on the image plane of the projection optical assembly PL, even by finely moving one or more lenses in the axial direction or in the direction perpendicular to the optical axis.

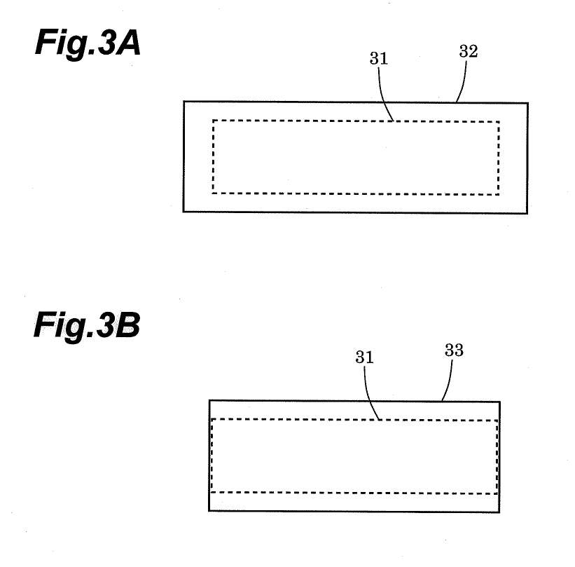

When the distortions are regular ones, the distortions appear in proportion to image heights in both of the vertical and horizontal directions, as schematically shown by a rectangular solid line 32 with respect to the rectangular unit exposure region 31 shown by a dashed line in FIG. 3A. On the other hand, with the aberration variation due to the light irradiation, there appears the distortion difference between vertical and horizontal distortions (or between distortions in two directions perpendicular to each other on the image plane), as schematically shown by a rectangular solid line 33 with respect to the rectangular unit exposure region 31 shown by a dashed line in FIG. 3B.

The distortion difference is a difference between a distortion amount in the vertical direction and a distortion amount in the horizontal direction. FIG. 3B shows a state in which a relatively large distortion occurs in the vertical direction, whereas almost no distortion occurs in the horizontal direction. Namely, in FIG. 3B, the distortions are not those proportional to image heights in both of the vertical and horizontal directions, but a relatively large distortion difference is made between the vertical and horizontal distortions. In the present embodiment, the variation in the distortion difference caused in the projection optical assembly PL in design by irradiation with the exposure light is 40.4 nm.

In the present embodiment, a light transmissive member having the absorption loss of not less than 2% for the exposure light is used as a correction member to generate a distortion difference in a tendency opposite to a tendency of the distortion difference generated in the projection optical assembly PL by irradiation with the exposure light, thereby to control the variation at a low level in the distortion difference generated in the projection optical assembly PL by irradiation with the exposure light. Specifically, as described below, at least one light transmissive member to generate the distortion difference in the tendency opposite to the tendency of the distortion difference generated in the projection optical assembly PL by irradiation with the exposure light is selected as the light transmissive member for the correction member.

Then at least one of a base material of the selected light transmissive member and a thin film on the base material is given the required absorption loss, thereby to obtain the correction member to replace the foregoing light transmissive member. At this time, the correction member may be formed so that at least one of a base material of the correction member and a thin film on the base material has the absorption loss of not less than 2% for the exposure light.

In the present embodiment, the correction member satisfies Conditional Expression (1) below. In Conditional Expression (1), TL is the transmittance of the projection optical assembly PL about the exposure light along the optical axis AX, as described above. T1 is the absorptance of the correction member about the light along the optical axis AX.

10<TL/T1<40 (1)

If the ratio is over the upper limit of Conditional Expression (1), the absorption loss of the correction member will be too small relative to the overall absorption loss of the projection optical assembly PL, which will result in failing to provide the correction member with a satisfactory function enough to suppress the aberration variation due to the light irradiation. If the ratio is below the lower limit of Conditional Expression (1) on the other hand, the absorption loss of the correction member will be too large, resulting in a significant reduction of the transmittance of the projection optical assembly PL and a reduction of throughput of the device eventually. For better exhibiting the effect of the present embodiment, the upper limit of Conditional Expression (1) can be set to 35 and the lower limit of Conditional Expression (1) to 15.

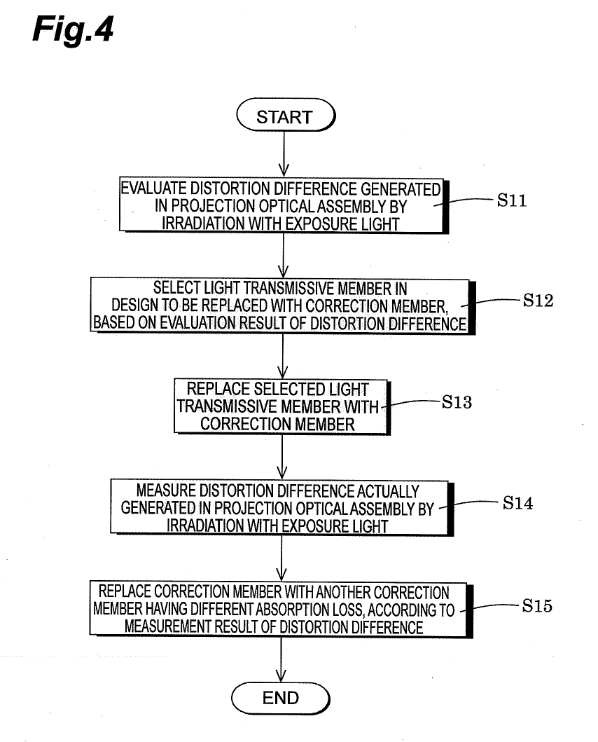

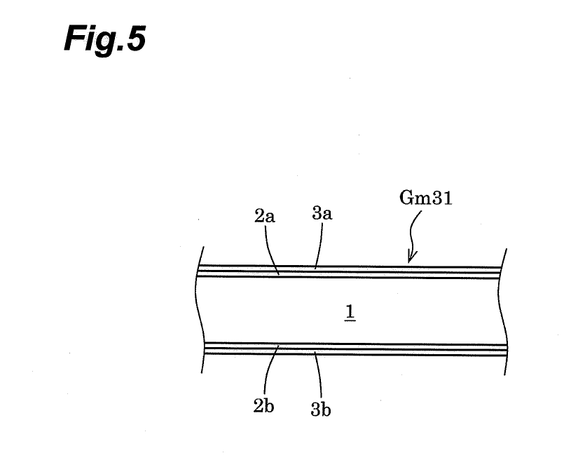

The below will describe specific examples of the projection optical assembly PL of the present embodiment and specific examples of the adjustment method of the projection optical assembly PL, with reference to FIGS. 4 and 5. In the adjustment method of the present embodiment, as shown in FIG. 4, an evaluation is carried out to evaluate the distortion difference generated in the projection optical assembly PL by irradiation with the exposure light (S11). Specifically, S11 is to perform a simulation analysis to check a nature of the distortion difference generated in the projection optical assembly PL in design by irradiation with the exposure light.

At the same time, with focus on the light transmissive members located at positions near the mask M or at positions near the wafer W, out of the light transmissive members G1-G31 forming the projection optical assembly PL, a simulation analysis is conducted to check natures of the distortion differences generated in these light transmissive members by irradiation with the exposure light. The reason for it is that the light transmissive members located at positions near the mask M or at positions near the wafer W are more suitable for the correction member for suppressing the variation in the distortion difference due to the light irradiation because a beam passes through them in a cross section more elongated in one direction, than the light transmissive members located near the pupil position of the projection optical assembly PL.

Next, a selection is carried out to select a light transmissive member in design to be replaced with the correction member, based on the evaluation result of the distortion difference in S11 (S12). Specifically, S12 is to select a light transmissive member that generates the distortion difference in the tendency opposite to the tendency of the distortion difference generated in the projection optical assembly PL by irradiation with the exposure light, as the light transmissive member for the correction member. In each of examples of the present embodiment, the plane-parallel plate G31 located nearest to the wafer W is adopted as the light transmissive member in design to be replaced with the correction member.

The next is to replace the light transmissive member selected in S12, with the correction member (S13). Specifically, S13 is to prepare the correction member Gm31 having the absorption loss of not less than 2% for the exposure light, in manufacture of the projection optical assembly PL, and to locate the correction member Gm31 in place of the plane-parallel plate G31 located nearest to the wafer W. A specific configuration and action of the correction member Gm31 according to each example will be described later.

In an actually-manufactured exposure device, the nature of the distortion difference actually generated in the projection optical assembly PL by irradiation with the exposure light may diverge from the result obtained by the simulation analysis, at an early stage or with time, because of manufacturing error of the projection optical assembly PL. Similarly, among actually-manufactured exposure devices, the nature of the distortion difference actually generated in the projection optical assembly PL by irradiation with the exposure light may differ device by device.

In the adjustment method of the present embodiment, a measurement is then carried out to measure the distortion difference actually generated in the projection optical assembly PL by irradiation with the exposure light (S14). Specifically, S14 is to perform an in-situ measurement of the distortion difference actually generated in the projection optical assembly PL by irradiation with the exposure light. At the same time, the nature of the distortion difference actually generated in the correction member Gm31 by irradiation with the exposure light is measured in situ

The following is to replace the correction member Gm31 with another correction member having a different absorption loss, according to the measurement result of the distortion difference in S14 (S15). Specifically, S15 is to prepare another correction member Gm31′ having a required absorption loss suitable for a current situation, as needed, for controlling the variation at a low level in the distortion difference actually generated in the projection optical assembly PL by irradiation with the exposure light in the exposure device in use, and to replace the currently-mounted correction member Gm31 with the other correction member Gm31′.

The correction member Gm31 according to each example is the light transmissive member that generates the distortion difference in the tendency opposite to the tendency of the distortion difference generated in the projection optical assembly PL by irradiation with the exposure light, and has the absorption loss of not less than 2% for the exposure light. Specifically, the correction member Gm31, as shown in FIG. 5, is composed of a base material 1 as a plane-parallel plate, antireflection films 2a, 2b formed on both surfaces of the base material 1, and light-absorbing films 3a, 3b formed on the antireflection films 2a, 2b. These light-absorbing films 3a, 3b are formed throughout the entire area of a light-passing region on the entrance surface and the exit surface of the base material 1 (which is an effective region of the base material 1). The light-absorbing films 3a, 3b are formed on the both surfaces (entrance and exit surfaces) of the base material 1 in the present embodiment, but it is sufficient to form the light-absorbing film on at least one of them. These light-absorbing films 3a, 3b may be formed in a uniform distribution throughout the entire area of the light-passing region (effective region of the base material 1) on the entrance and exit surfaces of the base material 1. When the light-absorbing films are formed throughout the entire area of the effective region of the base material 1, it becomes easier to set the thickness distribution of the light-absorbing films to a desired distribution and it is feasible to improve durability of the light-absorbing films.

In the first example, titanium oxide films (TiO₂ films) having the absorption loss of 1% for the exposure light were formed as the light-absorbing films 3a, 3b of the correction member Gm31. Therefore, the absorptance T1 about the light (axial ray) along the optical axis AX of the correction member Gm31 is represented by Formula (2a) below.

$$\begin{matrix}T 1 = 0.003 \times 0.6 + 0.0005 \times 2 + 0.01 \times 2 \\ = 0.0228 ( \text{=} 2.28 \% )\end{matrix} \qquad ( 2 a )$$

The first term of the right-hand side in Formula (2a) corresponds to the absorptance of the base material 1, the second term thereof to the absorptance of the antireflection films 2a, 2b, and the third term thereof to the absorptance of the light-absorbing films 3a, 3b. On the other hand, the transmittance TL of the projection optical assembly PL is reduced by the degree of the absorptance of the light-absorbing films 3a, 3b provided in the correction member Gm31 and is represented by Formula (3a) below.

$$\begin{matrix}TL = 0.75 - 0.01 \times 2 \\ = 0.73 ( \text{=} 73 \% )\end{matrix} \qquad ( 3 a )$$

In the correction member Gm31 according to the first example, therefore, TL/T1=0.73/0.0228=32.02, which satisfies Conditional Expression (1). In the first example, the variation in the distortion difference generated in the projection optical assembly PL by irradiation with the exposure light can be reduced from 40.4 nm before the adjustment to 28.1 nm.

In the second example, titanium oxide films having the absorption loss of 2% for the exposure light were formed as the light-absorbing films 3a, 3b of the correction member Gm31. Therefore, the absorptance T1 about the light (axial ray) along the optical axis AX of the correction member Gm31 is represented by Formula (2b) below.

$$\begin{matrix}T 1 = 0.003 \times 0.6 + 0.0005 \times 2 + 0.02 \times 2 \\ = 0.0428 ( \text{=} 4.28 \% )\end{matrix} \qquad ( 2 b )$$

On the other hand, the transmittance TL of the projection optical assembly PL is reduced by the degree of the absorptance of the light-absorbing films 3a, 3b provided in the correction member Gm31 and is represented by Formula (3b) below.

$$\begin{matrix}TL = 0.75 - 0.02 \times 2 \\ = 0.71 ( \text{=} 71 \% )\end{matrix} \qquad ( 3 b )$$

In the correction member Gm31 according to the second example, therefore, TL/T1=0.71/0.0428=16.59, which satisfies Conditional Expression (1). In the second example, the variation in the distortion difference generated in the projection optical assembly PL by irradiation with the exposure light can be reduced from 40.4 nm before the adjustment to 16.2 nm.

In the present embodiment, the correction member may satisfy Conditional Expression (4) below. In Conditional Expression (4), φP represents the smaller of partial diameters on the entrance and exit surfaces of the correction member and φE an effective diameter of the surface (entrance or exit surface) having the smaller partial diameter φP.

0.1<φP/φE<0.4 (4)

It is noted herein that a partial diameter is defined as follows: when the correction member is illuminated with a beam emerging with a predetermined numerical aperture from one point on the first surface, the partial diameter is the smaller of a diameter and a minor axis of an illuminated region on the surface (entrance or exit surface) of the correction member. In the present embodiment, the one point on the first surface can be a point on the optical axis. When the projection optical assembly has an eccentric field (off-axis field), a central point in the eccentric field region on the first surface can be used as the one point on the first surface. The predetermined numerical aperture in acquisition of the partial diameter φP can be the maximum numerical aperture on the entrance side (first surface side) of the projection optical assembly.

If the ratio is over the upper limit of Conditional Expression (4), the correction member will be located too close to the pupil plane, so as to result in failing to achieve a satisfactory correction effect of the distortion difference of the projection optical assembly. If the ratio is below the lower limit, a heat absorption amount of the correction member will be too large, so as to result in generating a too large change of aberration in short time.

In the first and second examples described above, the partial diameters φp in the correction member Gm31 are 22.4 on the entrance surface and 17.4 on the exit surface, and therefore φP is 17.4 by adopting the partial diameter φp on the exit surface. Since the effective diameter of this exit surface is 59.4, φP/φE=0.293, which satisfies Conditional Expression (4).

In each of the foregoing examples, the plane-parallel plate G31 located nearest to the wafer W is used as a light transmissive member in design to be replaced with the correction member. However, without having to be limited to this, a variety of forms can be contemplated as to the shape, the number, the arrangement position, etc. of the light transmissive member in design to be replaced with the correction member.

In each of the foregoing examples, the titanium oxide films are formed as the light-absorbing films 3a, 3b of the correction member Gm31. However, without having to be limited to this, the light-absorbing films can also be formed using appropriate metal films other than the titanium oxide films or appropriate films made of a material except for metal.

In each of the foregoing examples, the light-absorbing films 3a, 3b are formed on the antireflection films 2a, 2b of the base material 1. However, without having to be limited to this, the light-absorbing films can be formed directly on the base material. In this case as well, the light-absorbing films 3a, 3b may be formed throughout the entire area of the light-passing region on the entrance and exit surfaces of the base material 1 (the effective region of the base material 1), and may be formed in a uniform distribution throughout the entire area of the light-passing region on the entrance and exit surfaces of the base material 1.

In each of the foregoing examples, the thin films (light-absorbing films 3a, 3b) on the base material 1 have the absorption loss of not less than 2% for the wavelength of the exposure light, but the base material 1 itself may have the absorption loss of not less than 2% for the wavelength of the exposure light. In this case, the absorption loss can be not the absorption loss per unit length but the absorption loss per correction member (base material 1).

In the foregoing embodiment, the present invention is applied to the suppression of the variation in the distortion difference generated in the projection optical assembly PL by irradiation with the exposure light. However, without having to be limited to this, the present invention can also be applied to suppression of variation in another appropriate aberration except for the distortion difference generated in the projection optical assembly by irradiation with light, e.g., an axial astigmatic difference between a vertical line pattern and a horizontal line pattern (which will also be referred to hereinafter as “vertical-horizontal axial astigmatic difference”).

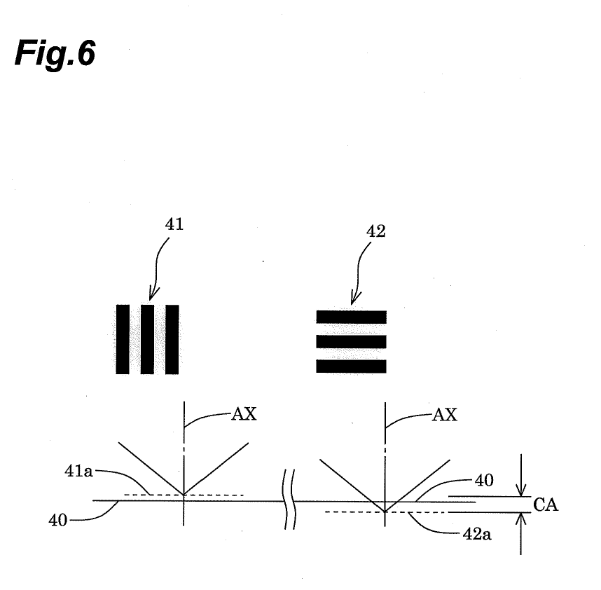

The vertical-horizontal axial astigmatic difference, as shown in FIG. 6, is a difference CA between a focus position 41a on the optical axis AX of light having passed through a vertical line pattern 41 and a focus position 42a on the optical axis AX of light having passed through a horizontal line pattern 42. In FIG. 6, a position 40 indicated by a solid line represents a theoretical image plane of the projection optical assembly.

As for the vertical-horizontal axial astigmatic difference, variation thereof can be effectively suppressed by arranging a correction member with a required absorption loss, in plane of a light transmissive member located at an intermediate position between a light transmissive member near the pupil of the projection optical assembly and a light transmissive member near the object plane or near the image plane. As described above, the variation in the distortion difference between distortions in two orthogonal directions on the image plane can be effectively suppressed by arranging the correction member with the required absorption loss in place of the light transmissive member near the object plane or near the image plane of the projection optical assembly. Furthermore, variation in spherical aberration can be effectively suppressed by arranging a correction member with a required absorption loss in place of a light transmissive member near the pupil of the projection optical assembly.

In the aforementioned embodiment, the projection optical assembly is formed of the combination of light transmissive members comprised of the four optical materials. However, without having to be limited to this, the light transmissive members such as the lenses forming the projection optical assembly may be made of one type of optical material.

In the aforementioned embodiment, the present invention is applied to the projection optical assembly as a dioptric system including no power-possessing reflecting mirror. However, without having to be limited to this, the present invention can also be applied similarly to the projection optical assembly as a catadioptric system including a power-possessing reflecting mirror and refracting optical elements.

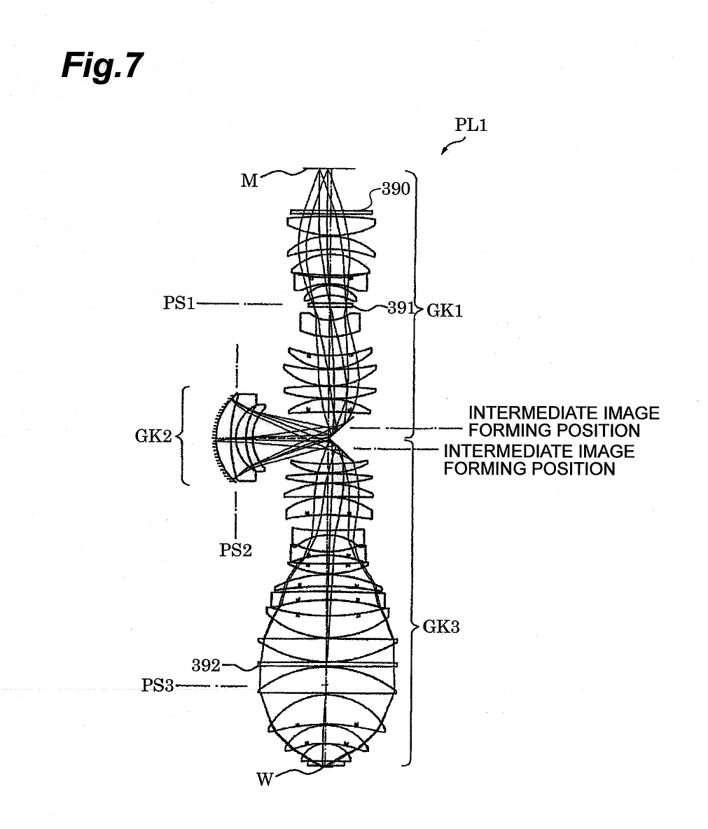

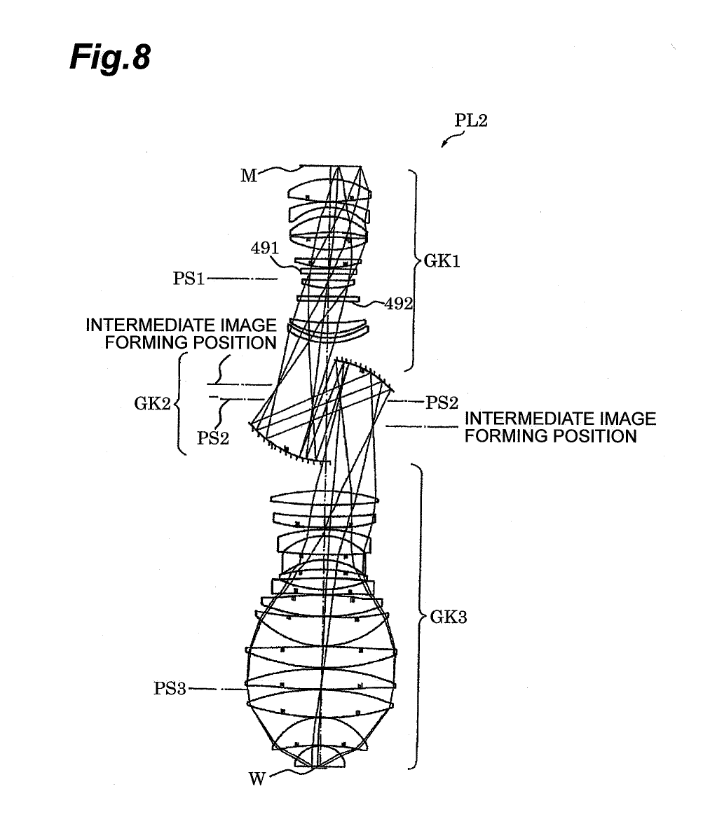

As described above, the correction member is not limited to the one arranged at the position near the image plane of the projection optical assembly (the second surface), but may be arranged at the position near the object plane of the projection optical assembly (the first surface), at the pupil position of the projection optical assembly or at a conjugate plane thereof, or at a position other than those in the projection optical assembly. FIGS. 7 and 8 show examples of projection optical assemblies in which the correction member is arranged.

The projection optical assembly PL1 shown in FIG. 7 is provided with a dioptric imaging optical system GK1 to form an intermediate image of the pattern of the mask M, a catadioptric imaging optical system GK2 to form an image of the intermediate image, and a dioptric imaging optical system GK3 to form as a final image an image of the intermediate image formed by the catadioptric imaging optical system GK2, on the surface (transfer surface) of the wafer W. This projection optical assembly PL1 has pupil planes PS1-PS3 as planes where an aperture stop is placed, and a conjugate plane thereof. Plane-parallel plates 391, 392 are located near the pupil plane PS1 and near the pupil plane PS3, respectively, and at least one of these plane-parallel plates 391, 392 can be used as a correction member. Another plane-parallel plate 390 located near the mask M may be used as a correction member. In this case, the plane-parallel plate 390 located near the mask M and at least one of the plane-parallel plates 391, 392 may be used as correction members.

The projection optical assembly PL2 shown in FIG. 8 is provided with a dioptric imaging optical system GK1 to form an intermediate image of the mask M, a catoptric imaging optical system GK2 to form an image of the intermediate image, and a dioptric imaging optical system GK3 to form as a final image an image of the intermediate image formed by the reflecting imaging optical system GK2, on the surface (transfer surface) of the wafer W. This projection optical assembly PL2 has pupil planes PS1-PS3 as planes where an aperture stop is placed, and a conjugate plane thereof. Plane-parallel plates 491, 492 are located near the pupil plane PS1 and the plane-parallel plate 491 can be used as a correction member. The other plane-parallel plate 492 may be used as a correction member. Furthermore, both of the plane-parallel plates 491, 492 may be used as correction members.

In the foregoing embodiment, when the aberration actually generated in the projection optical assembly PL diverges from the result obtained by the simulation analysis, the correction member Gm31 is replaced with another correction member having a different absorption loss. However, the replacement of the correction member Gm31 may be performed, for example, according to a change of an illumination condition in actual exposure. This illumination condition may be, for example, the σ value upon illumination on the first surface, or may be a state of distribution of light (typically, e.g., circular, annular, or multipolar shape) on the exit pupil of the illumination optical assembly.

The foregoing embodiment may be arranged in combination with a technique of controlling aberration by moving one or more optical members of the projection optical assembly PL in the axial direction or in the direction perpendicular to the optical axis or by inclining one or more optical members relative to the optical axis. In this case, it is possible to make narrower a drive range necessary for a drive unit to drive the one or more optical members. The embodiment may also be combined with a technique of controlling aberration by deforming an optical surface of one or more optical members of the projection optical assembly. In this case, it is possible to make a deformation amount of the optical surface smaller.

In the aforementioned embodiment, the mask can be replaced with a variable pattern forming device which forms a predetermined pattern on the basis of predetermined electronic data. The variable pattern forming device applicable herein can be, for example, a spatial light modulation element including a plurality of reflective elements driven based on predetermined electronic data. The exposure device using the spatial light modulation element is disclosed, for example, in U.S. Pat. Published Application No. 2007/0296936. Besides the reflective spatial light modulators of the non-emission type as described above, it is also possible to apply a transmissive spatial light modulator or a self-emission type image display device.

The exposure device of the foregoing embodiment is manufactured by assembling various sub-systems containing their respective components as set forth in the scope of claims in the present application, so as to maintain predetermined mechanical accuracy, electrical accuracy, and optical accuracy. For ensuring these various accuracies, the following adjustments are carried out before and after the assembling: adjustment for achieving the optical accuracy for various optical systems; adjustment for achieving the mechanical accuracy for various mechanical systems; adjustment for achieving the electrical accuracy for various electrical systems. The assembling from the various sub-systems into the exposure device includes mechanical connections, wire connections of electric circuits, pipe connections of pneumatic circuits, etc. between the various sub-systems. It is needless to mention that there is assembling of each of the sub-systems, before the assembling from the various sub-systems into the exposure device. After completion of the assembling from the various sub-systems into the exposure device, overall adjustment is carried out to ensure various accuracies as the entire exposure device. The manufacture of exposure device may be performed in a clean room in which the temperature, cleanliness, etc. are controlled.

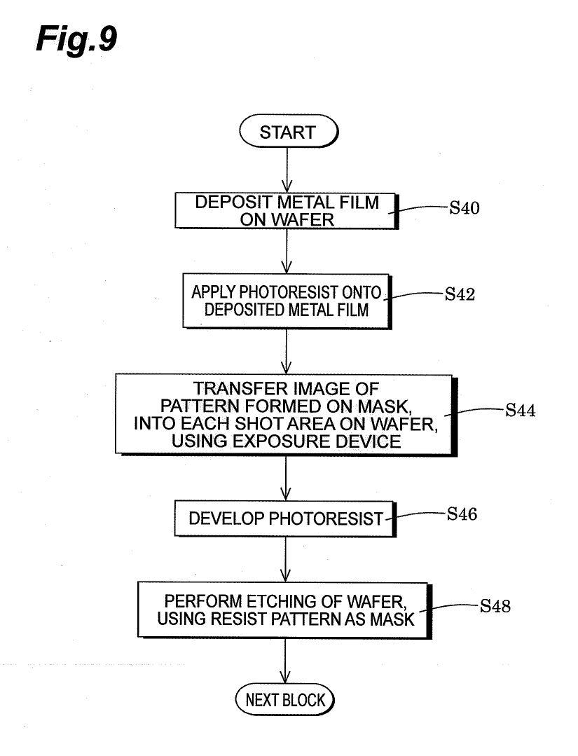

The following will describe a device manufacturing method using the exposure device according to the above-described embodiment. FIG. 9 is a flowchart showing manufacturing blocks of semiconductor devices. As shown in FIG. 9, the manufacturing blocks of semiconductor devices include depositing a metal film on a wafer W to become a substrate of semiconductor devices (S40), and applying a photoresist as a photosensitive material onto the deposited metal film (S42). The subsequent blocks include transferring a pattern formed on a mask (reticle) M, into each shot area on the wafer W, using the exposure device of the foregoing embodiment (S44: exposure block), and developing the wafer W after completion of the transfer, i.e., developing the photoresist on which the pattern has been transferred (S46: development block). Thereafter, using as a mask the resist pattern made on the surface of the wafer W in S46, processing such as etching is carried out on the surface of the wafer W (S48: processing block).

The resist pattern herein is a photoresist layer in which depressions and projections are formed in a shape corresponding to the pattern transferred by the exposure device of the above embodiment and which the depressions penetrate throughout. S48 is to process the surface of the wafer W through this resist pattern. The processing carried out in S48 includes, for example, at least either etching of the surface of the wafer W or deposition of a metal film or the like. In S44, the exposure device of the above embodiment performs the transfer of the pattern onto the wafer W coated with the photoresist, as a photosensitive substrate.

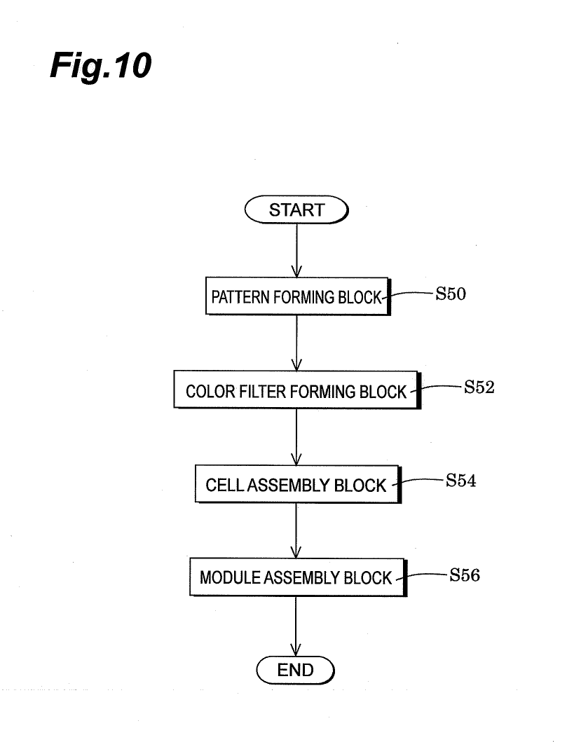

FIG. 10 is a flowchart showing manufacturing blocks of a liquid crystal device such as a liquid crystal display device. As shown in FIG. 10, the manufacturing blocks of the liquid crystal device include sequentially performing a pattern forming block (S50), a color filter forming block (S52), a cell assembly block (S54), and a module assembly block (S56). The pattern forming block of S50 is to form predetermined patterns such as a circuit pattern and an electrode pattern on a glass substrate coated with a photoresist, as a plate P, using the exposure device of the aforementioned embodiment. This pattern forming block includes an exposure block of transferring a pattern to a photoresist layer, using the exposure device of the above embodiment, a development block of performing development of the plate P on which the pattern has been transferred, i.e., development of the photoresist layer on the glass substrate, to make the photoresist layer in a shape corresponding to the pattern, and a processing block of processing the surface of the glass substrate through the developed photoresist layer.

The color filter forming block of S52 is to form a color filter in which a large number of sets of three dots corresponding to R (Red), G (Green), and B (Blue) are arrayed in a matrix pattern, or in which a plurality of filter sets of three stripes of R, G, and B are arrayed in a horizontal scan direction. The cell assembly block of S54 is to assemble a liquid crystal panel (liquid crystal cell), using the glass substrate on which the predetermined pattern has been formed in S50, and the color filter formed in S52. Specifically, for example, a liquid crystal is poured into between the glass substrate and the color filter to form the liquid crystal panel. The module assembly block of S56 is to attach various components such as electric circuits and backlights for display operation of this liquid crystal panel, to the liquid crystal panel assembled in S54.

The present invention is not limited just to the application to the exposure devices for manufacture of semiconductor devices, but can also be widely applied, for example, to the exposure devices for display devices such as the liquid crystal display devices formed with rectangular glass plates, or plasma displays, and to the exposure devices for manufacture of various devices such as imaging devices (CCDs and others), micro machines, thin film magnetic heads, and DNA chips. Furthermore, the present invention is also applicable to the exposure (exposure devices) for manufacture of masks (photomasks, reticles, etc.) on which mask patterns of various devices are formed, by the photolithography process.

The foregoing embodiment uses the light of the i-line as the exposure light, but the present invention, which does not have to be limited to it, may also be applied to other appropriate laser light sources to supply, for example, the ArF excimer laser light (wavelength: 193 nm) or the KrF excimer laser light (wavelength: 248 nm).

In the foregoing embodiment, it is also possible to apply a technique of filling the interior of the optical path between the projection optical assembly and the photosensitive substrate with a medium having the refractive index larger than 1.1 (typically, a liquid), which is so called a liquid immersion method. In this case, it is possible to adopt one of the following techniques as a technique of filling the interior of the optical path between the projection optical assembly and the photosensitive substrate with the liquid: the technique of locally filling the optical path with the liquid as disclosed in International Publication WO99/49504; the technique of moving a stage holding the substrate to be exposed, in a liquid bath as disclosed in Japanese Patent Application Laid-open No. 6-124873; the technique of forming a liquid bath of a predetermined depth on a stage and holding the substrate therein as disclosed in Japanese Patent Application Laid-open No. 10-303114, and so on. The teachings of International Publication WO99/49504, Japanese Patent Application Laid-open No. 6-124873, and Japanese Patent Application Laid-open No. 10-303114 are incorporated herein by reference.

In the foregoing embodiment, the present invention is applied to the projection optical assembly for projecting the pattern of the mask onto the photosensitive substrate in the exposure device, but the present invention, which does not have to be limited to it, can also be applied to any projection optical assembly for forming an image of a first surface on a second surface, using light of a predetermined wavelength.

As described above, the present embodiment can realize the projection optical assembly capable of controlling the aberration variation due to the light irradiation at a low level. Accordingly, the exposure device of the present invention can accurately transfer a microscopic pattern onto the photosensitive substrate, using the projection optical assembly to control the aberration variation due to the light irradiation at a low level, and therefore can manufacture satisfactory devices eventually.

What is claimed is:

1. A projection optical assembly for forming an image of a first surface on a second surface, using light of a predetermined wavelength, the projection optical assembly comprising:
a correction member which, when irradiated with the light of the predetermined wavelength, generates an aberration in a tendency opposite to a tendency of the aberration generated in the projection optical assembly by irradiation with the light of the predetermined wavelength,
wherein the correction member is a light transmissive member having an absorption loss of not less than 2% for the light of predetermined wavelength.

2. The projection optical assembly according to claim 1,
wherein the correction member comprises a base material and a thin film on the base material, and
wherein at least one of the base material of the correction member and the thin film on the base material has the absorption loss of not less than 2% for the light of the predetermined wavelength.

3. The projection optical assembly according to claim 1,
wherein when TL represents a transmittance about light along the optical axis of the projection optical assembly and T1 an absorptance about the light along the optical axis of the correction member, a ratio of the transmittance TL to the absorptance T1 satisfies the following condition:
10<TL/T1<40,
where the transmittance TL and the absorptance T1 are defined for the light of the predetermined wavelength.

4. The projection optical assembly according to claim 1,
wherein the aberration includes a distortion difference between distortions in two directions perpendicular to each other on the second surface.

5. The projection optical assembly according to claim 4,
wherein the correction member is located at a position near the first surface or at a position near the second surface.

6. The projection optical assembly according to claim 4,
wherein when φP represents a smaller partial diameter out of partial diameters on an entrance surface and an exit surface of the correction member and φE an effective diameter of the surface providing the smaller partial diameter φP, a ratio of the partial diameter φP to the effective diameter φE satisfies the following condition:
0.1<φP/φE<0.4,
where a partial diameter is defined as follows: when an optical member is illuminated with a beam emitted with a predetermined numerical aperture from a point on the first surface, the partial diameter is the smaller of a diameter and a minor axis of an illuminated region on a surface of the optical member.

7. The projection optical assembly according to claim 2,
wherein the thin film of the correction member has an antireflection film provided on the base material, and a light-absorbing film provided on the antireflection film.

8. The projection optical assembly according to claim 7,
wherein the light-absorbing film is a thin film of metal.

9. The projection optical assembly according to claim 7,
wherein the light-absorbing film is formed throughout an entire area of a light-passing region on an entrance surface or an exit surface of the correction member.

10. The projection optical assembly according to claim 1,
wherein the base material is formed of an optical material having transparency for the light of the predetermined wavelength.

11. The projection optical assembly according to claim 1,
wherein the correction member is replaceable with another correction member having an absorption loss different from that of the correction member.

12. The projection optical assembly according to claim 11,
the projection optical assembly being used in combination with an illumination optical assembly for illuminating the first surface, said illumination optical assembly being capable of changing over an illumination condition for illumination on the first surface between a first illumination condition and a second illumination condition different from the first illumination condition,
wherein upon a changeover of the illumination condition, the correction member is replaced with the other correction member.

13. An adjustment method of a projection optical assembly for forming an image of a first surface on a second surface, using light of a predetermined wavelength, the adjustment method comprising:
arranging in an optical path a light transmissive member having an absorption loss of not less than 2% for the light of the predetermined wavelength, as a correction member which generates an aberration in a tendency opposite to a tendency of the aberration generated in the projection optical assembly by irradiation with the light of the predetermined wavelength.

14. The adjustment method according to claim 13, comprising:
measuring the aberration actually generated in the projection optical assembly by irradiation with the light of the predetermined wavelength; and
replacing the correction member with another correction member having a different absorption loss, according to the measurement result of the aberration.

15. The adjustment method according to claim 13, comprising:
evaluating the aberration generated in the projection optical assembly by irradiation with the light of the predetermined wavelength; and
selecting a light transmissive member in design to be replaced with the correction member, based on the evaluation result of the aberration.

16. The adjustment method according to claim 13,
wherein the projection optical assembly is used in combination with an illumination optical assembly for illuminating the first surface, said illumination optical assembly being capable of changing over an illumination condition for illumination on the first surface between a first illumination condition and a second illumination condition different from the first illumination condition,
said adjustment method comprising: replacing the correction member with another correction member having a different absorption loss, upon a changeover of the illumination condition.

17. The adjustment method according to claim 13,
wherein the aberration includes a distortion difference between distortions in two directions perpendicular to each other on the second surface.

18. The adjustment method according to claim 17,
wherein the correction member is located at a position near the first surface or at a position near the second surface.

19. An exposure device comprising the projection optical assembly as defined in claim 1 for, based on light from a predetermined pattern set on the first pattern, projecting the predetermined pattern onto a photosensitive substrate set on the second surface.

20. An exposure method comprising:
guiding light from a predetermined pattern set on the first surface to a projection optical assembly to project the predetermined pattern onto a photosensitive substrate set on the second surface; and
adjusting the projection optical assembly, using the adjustment method as defined in claim 13

21. A device manufacturing method comprising:
performing exposure of the photosensitive substrate with the predetermined pattern, using the exposure method as defined in claim 20;
developing the photosensitive substrate on which the predetermined pattern has been transferred, to form a mask layer in a shape corresponding to the predetermined pattern on a surface of the photosensitive substrate; and
processing the surface of the photosensitive substrate through the mask layer.
